(19) United States
(12) Patent Application Publication
(10) Pub. No.: US 2002/0127859 A1
(43) Pub. Date: Sep. 12, 2002

(54) Compositions and methods for the selective etching of polysilicon for wafer reclamation

(76) Inventor: Biao Wu, Chanhassen, MN (US)

Correspondence Address: KAGAN BINDER, PLLC, Intellectual Property Attorneys, Maple Island Building, Suite 200, 221 Main Street North, Stillwater, MN, 55082, US

(21) Appl. No.: 10/139,950

(22) Filed: May 6, 2002

Related U.S. Application Data
(63) Continuation of application No. 09/428,342, filed on Oct. 27, 1999.

(51) Int. Cl. H01L 21/302; H01L 21/461

(52) U.S. Cl. 438/689

(57) ABSTRACT

The present invention provides methods for selectively stripping polysilicon-containing films from oxide surfaces using an etching composition including a fluoride ion source and an oxidant. The etching composition exhibits a high degree of selectivity between polysilicon and oxide, such that the underlying oxide surface or film layer acts as a stop layer, thereby protecting the underlying substrate from the etching composition. Furthermore, the etching composition is effective at substantially at ambient temperature, thereby avoiding the potential safety concerns that may arise when chemicals are heated in manufacturing situations.

### FIELD OF THE INVENTION

This invention relates to methods and compositions for selectively removing a polysilicon-containing film from an oxide surface by using an aqueous, acidic etching composition comprising a relatively small amount of a fluoride ion source and a relatively large amount of an oxidant. Because the composition exhibits a high degree of selectivity between polysilicon and oxide films, the composition and methods are particularly useful in wafer reclamation processes.

### BACKGROUND OF THE INVENTION

Wafer reclamation is becoming more important to integrated circuit manufacturers as the cost of test wafers continues to rise. Wafer reclamation is a process in which layers of films, or “film stacks”, on semiconductor wafer substrates are removed so that the wafer can be reused. Of course, in order for wafer reclamation to be practically and economically feasible, the method of removing the film stacks must not only be capable of removing substantially all of the film layers, but must be capable of doing so at a cost less than that of replacing the wafer. Furthermore, the process must not damage the surface of the wafer. Finally, the process of removing the film stacks desirably proceeds at a reasonable rate so that the utilization of the reclamation process is practical in a typical manufacturing setting.

While many kinds of films, such as oxide films, nitride films, and metal films, are relatively easy to selectively remove using conventional reclamation chemicals and techniques, the selective removal of other films, such as polysilicon-containing films, can be difficult. In many cases, this difficulty arises due to the typical film stack configuration utilized when one of the films in the stack is a polysilicon-containing film. That is, in such film stacks, polysilicon films are typically formed over an underlying oxide film, e.g., a film of silicon oxide. The silicon oxide film itself may be directly formed over the wafer substrate itself. Both films must be removed in order to effectively reclaim a wafer comprising such a film stack. Yet, conventional reclamation chemicals are generally not useful in this application because they typically either lack the necessary level of selectivity for polysilicon relative to silicon oxide so as to avoid damaging the underlying wafer, remove the film stack too slowly as to be impractical to use in a manufacturing setting, or require that removal occur at high temperatures making it more difficult and expensive to handle the reclamation chemicals safely.

For example, one conventional process often utilized to remove a polysilicon/silicon oxide film stack involves applying a hot (i.e., approximately 95° C.) aqueous composition comprising tetramethyl ammonium hydroxide (TMAH) to the wafer to strip the polysilicon film. Once the hot TMAH composition has been utilized to remove substantially all of the polysilicon, another chemical, e.g., aqueous hydrofluoric acid (HF), would be used in accordance with conventional practices to preferentially remove the newly exposed oxide film without significantly damaging the underlying wafer substrate.

The use of hot TMAH does have certain positive performance characteristics. For instance. TMAH selectively etches polysilicon relative to silicon oxide, and, as a result, will effectively etch the polysilicon film without unduly etching the underlying oxide film or the wafer below it. Indeed, the ratio of the rate at which the hot TMAH etches polysilicon relative to the rate at which the same hot TMAH etches oxide is typically 1000:1. The practical effect of the very high selectivity of TMAH relative to silicon oxide is that the underlying oxide film acts as a “stop layer”, essentially stopping the etching process before the TMAH reaches, and could potentially damage, the wafer substrate.

Notwithstanding these advantages, the utilization of TMAH in reclamation processes can be suboptimal for many reasons. First of all, although TMAH exhibits excellent polysilicon/silicon oxide stripping selectivity, the overall etch rate provided by even hot TMAH is typically very slow and the etch rate provided by TMAH at substantially ambient temperature is even slower. Specifically, the etch rate for TMAH heated to approximately 95° C. ranges from about 600Å per minute to about 800Å per minute for polysilicon films which means that a 16μm polysilicon film will take over three hours to etch. This etch rate is too slow to be practically feasible for use in many reclamation processes. Secondly, TMAH may not be compatible with materials desirably used to fabricate some kinds of reclamation process equipment. For example, contact with TMAH may result in the undesirable discoloration of components of reclamation equipment fabricated from polyvinylidene fluoride (PVDF). Third, TMAH typically must be heated to approximately 95° C. in order to provide even the aforementioned relatively slow etch rates. Heating the TMAH necessitates the inclusion of a heater in the reclamation processing system, which may present additional cost and space issues. Additionally, relatively hot processing in a manufacturing setting is generally considered to be less desirable than ambient processes in that the handling of heated chemicals is more challenging than is handling the same or different chemicals at ambient temperature.

Aqueous compositions including nitric acid (HNO₃), hydrofluoric acid (HF), and water (H₂O) have been used in the past in the manufacture of integrated circuits. Conventionally, these compositions have included from about 50% to about 60% by volume of aqueous HNO₃ (typically about 70 weight % solids), 10% or more aqueous HF (typically about 50 weight % solids), with the remainder being H₂O. See, for example, “Silicon Processing for the VLSI era - Volume 1, process technology”, by S. Wolf and R. N. Tauber, Lattice Press, Sunset Beach, CA, page 531-532, 1986. These compositions exhibit very fast etch rates for polysilicon, e.g., from about 10μ/min to about 80μ/min, but unfortunately, etch oxide films faster than polysilicon-containing films. In other words, these compositions exhibit selectivity that favors oxide, not polysilicon. Thus, these compositions have been very useful in cleaning and etching applications where selectivity favoring polysilicon is generally not required. However, in reclamation processes, where an oxide layer desirably acts as a “stop layer”, this lack of stripping selectivity between polysilicon-containing films and oxide films is undesirable. These compositions can etch through the oxide before all the polysilicon is removed, thereby damaging the underlying wafer. As a result, these aqueous HF/HNO₃ compositions are not considered to be useful for reclamation applications.

What is needed, therefore, are reclamation compositions and processes that provide the desired stripping selectivity between polysilicon-containing films and oxide films, i.e., in which the etching selectivity favors polysilicon so that the silicon oxide layer can act as a stop layer to protect the wafer as the polysilicon is removed. Such compositions and processes desirably would exhibit this selectivity while also providing acceptably fast etch rates. It would further be desirable for such compositions to be compatible with materials such as PVDF that may be used in the manufacture of reclamation process equipment. Finally, it would be advantageous if such reclamation compositions and processes would be effective at substantially ambient temperatures so that the cost and safety concerns that are sometimes associated with hot chemical processes could be avoided.

### SUMMARY OF THE INVENTION

According to the present invention, the above objectives and other objectives apparent to those skilled in the art upon reading this disclosure are attained by the present invention which is drawn to methods for use in wafer reclamation that utilize an etching composition which comprises a fluoride ion source and an oxidant. Specifically, the etching composition preferably is acidic and comprises a relatively large amount of oxidant and a relatively small amount of the fluoride ion source so that the composition shows favorable selectivity for etching polysilicon relative to silicon oxide. Due to this selectivity, the etching composition of the present invention can remove a polysilicon film from an oxide surface while leaving an underlying substrate, such as a semiconductor wafer, substantially undamaged. Additionally, and in contrast to prior art etching compositions comprising TMAH, etching compositions in accordance with the present invention can remove polysilicon-containing films from oxide surfaces at extremely high etch rates, i.e., at rates of from about 1μm to about 5μm per minute. Thus, whereas conventional TMAH solutions can take up to 3 hours to etch a 16μm polysilicon film, the etching compositions of the present invention can remove such a film in only from about 3 minutes to about 16 minutes. Furthermore, due to the unique composition of the etching composition, it is capable of providing such high etch rates at substantially ambient temperature, and without substantially damaging manufacturing equipment comprising many plastic materials, including PVDF.

Thus, in one aspect, the present invention provides a polysilicon film etching composition comprising an oxidant, a source of fluoride ions, and water. Preferably, the volume ratio of the oxidant to the fluoride ion source is sufficiently high such that the etching composition has a polysilicon/oxide stripping selectivity of at least about 2 or more. The etching composition desirably has an acidic pH. In preferred embodiments, the oxidant is nitric acid and the fluoride ion source is hydrofluoric acid, with the ratio of HNO₃ to HF being high enough so that the composition etches polysilicon relative to silicon oxide with favorable selectivity. This is an unexpected and surprising result inasmuch as conventional HNO₃/HF compositions exhibit the opposite selectivity, i.e., favoring oxide over polysilicon.

Due also to the selectivity of the etching composition, and furthermore due to the extremely high etch rates that can be achieved, the etching composition of the present invention finds particular utility in the reclamation of semiconductor wafers. Thus, in yet another aspect, the present invention provides a method of reclaiming a semiconductor wafer substrate bearing a film stack comprising a polysilicon-containing film overlying an oxide film. Specifically, the method comprises the steps of causing an etching composition in accordance with the present invention to contact the polysilicon-containing film under conditions effective to remove at least a portion of the polysilicon-containing film from the substrate thereby exposing the oxide film. The exposed oxide film is then removed from the substrate using any desired chemistry, and the wafer is thus reclaimed.

As used herein, the phrase “polysilicon/oxide stripping selectivity” means the ratio of the strip rate of a polysilicon film to the strip rate of an oxide film as achieved by an etching composition and can be represented by the mathematical formula Eₚ/Eₒ where Eₚ is the rate in μm per minute at which the composition etches polysilicon film at 22° C., and Eₒ is the rate, in μm/min at which the same composition etches silicon oxide film at 22° C. Etch rate can be determined by, for example, by measuring the film thickness before and after etching, and then calculating etch rate according to the following formula: ER=(Tₚᵣₑ−Tₚₒₛₜ)/t where ER is etch rate, Tₚᵣₑ is the film thickness in microns prior to etching, Tₚₒₛₜ is the film thickness in microns after etching and t is the duration of etching in minutes. Desirably, the film thickness measurements are made utilizing an ellipsometer at either 9 points or 25 points. If the stripping selectivity as calculated is >1the composition is considered to favor polysilicon relative to silicon oxide. If the stripping selectivity is calculated to be <1 the composition is considered to favor silicon oxide relative to polysilicon. For reclamation processes, it would be desirable for the selectivity to be substantially >1, e.g., at least about or more preferably 10 or more, more preferably 10 to 1000, most preferably about 50 so that the silicon oxide layer can act as a stop layer to protect the wafer as the polysilicon layer is etchingly removed.

Unless otherwise indicated, as used herein, all references to percentages are percentages by volume of the etching composition.

### BRIEF DESCRIPTION OF THE FIGURES

The above mentioned and other advantages of the present invention, and the manner of attaining them, will become more apparent and the invention itself will be better understood by reference to the following description of the embodiments of the invention taken in conjunction with the accompanying drawing, wherein:

FIG. 1 is a side schematic view of one representative system capable of treating a plurality of substrates with an aqueous, acidic etching composition comprising a fluoride ion source and an oxidant in accordance with the present invention, wherein the system may typically comprise one to four wafer cassettes and shows a central spray post for the spray delivery of the etching composition;

FIG. 2 is a top cross-sectional schematic view of a preferred embodiment of the system shown in FIG. 1, wherein the cross-section is taken along line A-A, and wherein the system comprises two wafer cassettes and shows both a central spray post and a side bowl spray post for the spray delivery of an etching composition in accordance with the present invention.

FIG. 3 is a top cross-sectional schematic view of a preferred embodiment of the system shown in FIG. 1, wherein the cross-section is taken along line A-A, and wherein the system comprises four wafer cassettes and shows both a central spray post and a side bowl spray post for the spray delivery of an etching composition in accordance with the present invention.

### DETAILED DESCRIPTION OF THE INVENTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

The present invention provides a composition and methods for use in selectively stripping polysilicon-containing films relative to oxide films. Specifically, the preferred etching compositions of the present invention are aqueous, acidic compositions compnrsing a relatively large amount of an oxidant and a relatively small amount of a fluoride ion source. The oxidant acts to oxidize the exposed polysilicon, which the fluoride ion source then etches according generally to the following reaction:

Si+HNO₃+6HF ═H₂SiF₆ +HNO₂+H₂+H₂O

Because the fluoride ion source does not appreciably etch polysilicon prior to its oxidation, and further because of the ratio of the oxidant to the fluoride ion source utilized in the etching composition of the present invention, a very high polysilicon/oxide selectivity can be achieved. Due to this high selectivity, the etching composition of the present invention is particularly useful in applications where a polysilicon film layer is desirably removed from an underlying oxide film layer, while the substrate below the oxide is left substantially unaffected by the etching process. For example, the etching compositions of the present invention are particularly useful in wafer reclamation processes wherein a film stack comprising a polysilicon-containing film and an underlying oxide film are desirably removed from a silicon wafer substrate. In this application, the polysilicon-containing layer would be removed with the etching composition of the present invention, and the remaining oxide layer subsequently removed using a convention chemical useful to remove such an oxide layer.

The oxidant of the aqueous etching composition may be any substance capable of oxidizing a polysilicon-containing film. For example, suitable oxidants include, but are not limited to, nitric acid, ozone, hydrogen peroxide, combinations thereof, and the like. Preferably, the oxidant utilized in the etching composition has a strong oxidizing capability and is acidic. For example, a preferred oxidant for use in the etching composition of the present invention comprises nitric acid.

The fluoride ion source may be any substance capable of providing a fluoride ion to the etching for etching the oxidized polysilicon. Suitable fluoride ion sources include, but are not limited to, hydrofluoric acid, ammonium fluoride, buffered hydrofluoric acid, potassium fluoride, combinations thereof and the like. Preferably, the fluoride ion source utilized in the etching composition of the present invention comprises aqueous hydrofluoric acid.

The etching composition of the present invention further comprises an amount of water as a solvent. As used herein, the term “water” is meant to include water, distilled water, filtered water, ultrapure deionized water, combinations thereof, and the like.

The etching composition of the present invention desirably has an acidic pH, i.e., a pH of less than about 7, preferably 5 or less, more preferably 3 or less, and most preferably less than 1. In certain embodiments, an acidic pH may be obtained simply by the choice of oxidant and/or fluoride ion source and the ratio of these two components. For example, both HNO₃ and HF are acidic in and of themselves. If this is not the case, that is, if an acidic pH is not obtained simply by blending the oxidant, the fluoride ion source and water, then the etching composition may desirably comprise an additional hydrogen ion source or other suitable lewis acid capable of lowering the pH to the desired level. Such hydrogen ion sources include, but are not limited to, hydrochloric acid, sulfuiric acid, acetic acid, phosphoric acid, citric acid, combinations of these, and the like.

The etching composition of the present invention may also include optional ingredients that, for example, enhance the usability and/or performance of the etching composition. For example, the etching composition may optionally include amounts of stabilizers, surfactants, buffering agents, or combinations thereof. If included, such optional ingredients are desirably included in an amount that produces the desired effect, as may readily be ascertained by one of ordinary skill in the art.

Particular formulations of an etching composition in accordance with the present invention can be determined with a view toward desired strip parameters, i.e., strip rate and polysilicon/oxide stripping selectivity. In general, enough of the oxidant should be included so that the oxidation of the polysilicon-containing film proceeds at a rate such that a reasonable strip rate is achieved. Additionally, enough of the fluoride ion source should be included to remove the oxidized polysilicon at a reasonable rate so that the oxidant may continue to oxidize the polysilicon-containing film. Furthermore, the ratio of the amount of oxidant to the amount of fluoride ion source is desirably such that the polysilicon/oxide stripping selectivity is at least about 2 or more, preferably 10 or more, more preferably 10 to 1000, most preferably about 50.

Of course, relative amounts of the oxidant to the fluoride ion source that will achieve these objectives will depend on the particular combination of oxidant and fluoride ion source chosen. Additionally, the particular oxidant and fluoride ion source will also determine the amount of water that will desirably be added to produce an etching composition in accordance with the present invention. For example, in an etching composition wherein the oxidant is concentrated. e.g., aqueous concentrated nitric acid at 70% solids, and the fluoride ion source is concentrated. e.g, aqueous hvdrofluoric acid at 50% solids, the oxidant and fluoride ion source may simply be mixed together in a ratio that results in the desired polysilicon/oxide stripping selectivity, i.e., at least about 2 or more, preferably 10 or more, more preferably 10 to 1000, most preferably about 50. That is, inasmuch as these acids are provided as compositions that include an amount of water, water need not be added to the etching composition as a separate component. The use of concentrated, aqueous acids is preferred as the use of more concentrated solutions will provide an etching composition with a faster etch rate. Of course, if it is desired to reduce the etch rate, more dilute chemicals could be used.

Bearing these considerations in mind, in preferred etching compositions wherein the oxidant comprises concentrated aqueous nitric acid (70% solids) and the fluoride ion source comprises concentrated, aqueous hydrofluoric acid (49% solids), it is preferred that the etching composition comprise less than 5% of the aqueous, concentrated hydrofluoric acid and at least 35% of the aqueous, concentrated nitric acid, with the remainder of the etching composition comprising water. More preferably, the etching composition comprises from about 0.01%,to about 5% of the concentrated, aqueous hydrofluoric acid and from about 50% to about 97% of the concentrated, aqueous nitric acid, with the remainder of the etching composition comprising water. Even more preferably, the etching composition comprises from about 0.5% to about 3% of the concentrated, aqueous hydrofluoric acid and from about 65% to about 70% of the concentrated, aqueous nitric acid, with the remainder of the etching composition comprising water. Most preferably, the etching composition comprises from about 2% to about 5% aqueous, concentrated hydrofluoric acid and from about 95% to about 97% aqueous, concentrated nitric acid, with the remainder of the etching composition comprising water.

Although compositions comprising 50-60% concentrated aqueous nitric acid, 10% or more aqueous, concentrated hydrofluoric acid and the remainder water have conventionally been used in cleaning and etching applications during the manufacture of integrated circuits, such compositions are not known to exhibit high strip selectivity between polysilicon and oxide. In fact, such compositions are known to favor silicon oxide. Thus, such compositions have never been effectively utilized, if at all, in reclamation processes. Applicant has now surprisingly discovered that, by simply increasing the relative amount of nitric acid relative to hydrofluoric acid, a composition with a very favorable polysilicon/oxide strip selectivity can be obtained.

The etching composition in accordance with the present invention are further advantageous over prior art etching compositions in that they exhibit a very high strip rate of polysilicon, i.e., from about 1μ/min to about 5μ/min. Thus, whereas prior art compositions comprising hot TMAH can take up to three hours to etch a 16μ polysilicon film, the etching composition of the present invention is capable of etching such a film in from about 3 minutes to about 16 minutes. Also significantly advantageous is the fact that the etching composition of the present invention is capable of achieving these high strip rates without being substantially heated, and in fact, can provide these strip rates at substantially ambient temperature. Finally, the etching composition of the present invention is substantially compatible with many materials, such as PVDF, PFA and PTFE, used to manufacture parts used in processing equipment for semiconductor wafer devices, whereas conventional compositions comprising hot TMAH can discolor parts made of these materials.

As a result of these advantageous properties of the etching composition, the etching composition of the present invention may advantageously be used to reclaim a semiconductor wafer substrate having a film stack thereon comprising a polysilicon-containing film provided over an underlying oxide film. More specifically, the methods of the present invention involve contacting the substrate from which a polysilicon-containing film is to be removed with the etching composition of the present invention under conditions effective to remove at least a portion preferably at least substantially all, of the polysilicon-containing film, thereby exposing at least a portion of the oxide film. The exposed oxide film may then be removed from the semiconductor wafer using any of a variety of conventional chemical compositions known to be capable of etching oxide films. Although the etching composition may be heated, the aforementioned strip rates and selectivity can be achieved without substantially heating the etching composition, and thus, the etching composition is desirably caused to contact the substrate while at substantially ambient temperature.

The etching composition in accordance with the method of the present invention may be applied to the substrate in one or more immersive and/or non-immersive manners. For example, the substrate may be immersed into the etching composition, i.e., as in a wet bench or a cascade type system of the type commercially available under the trade designation Omega 1000Tm, 2000TM, or 4000TM from YieldUP International, Inc., Mountain View, CA. Alternatively, the etching composition may be caused to flowably contact the surface of the substrate by, e.g., by dispensing the etching composition in a fluid stream from a source operably placed so that the etching composition contacts the substrate. As another option, the etching composition may be sprayed onto the substrate(s) to be stripped using an appropriate spraying apparatus.

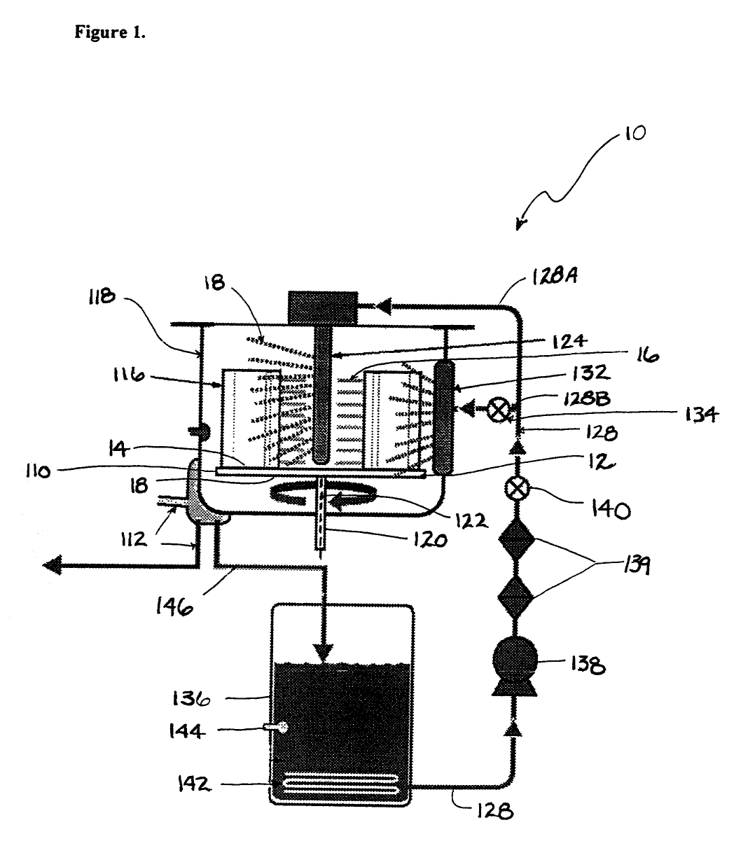

One particularly preferred type of apparatus that may be used to spray substrates with the etching composition in accordance with the present invention is the centrifugal spray processor commercially available from FSI International, Chaska, Minnesota, preferably under one or more of the trade designations MERCURY®, SATURN®, TITAN®, or ZETA®. Such spray systems are particularly advantageous in that they are closed systems, thus further enhancing the safety of the method of the present invention. One example of such a centrifugal spray processing system schematically representative of the MERCURY® spray processor is illustrated in FIG. 1.

FIG. 1 shows a System 10, as illustrated, is adapted to strip at least a portion of a surface of one or more substrates 16 with an etching composition comprising an oxidant and a fluoride ion source. Generally, system 10 comprises chamber 118, fluid supply line 128, rotatable support 12, central spray post 124, side bowl spray post 132, and exhaust and drain line 112. Chamber 118 is capable of housing one or more semiconductor wafer substrates 16 that are to be treated upon contact with etching composition 18.

Fluid supply line 128 serves to supply etching composition from etching composition supply 136 into chamber 118. Fluid supply line 128 may optionally include pump 138 to aid in motivating etching composition from etching composition supply 136 to chamber 18. Fluid supply also may optionally include filters 139 and valve 140, which allows for the addition of a standard rinse supply line (not shown) so that when valve 140 is activated, fluid supply line 128 serves to supply a rinse fluid, such as nitrogen or distilled water, to chamber 118. Fluid supply line 128 is bifurcated into center spray post fluid supply line 128A and side bowl spray post fluid supply line 128B. Center spray post fluid supply line 128A and side bowl fluid supply line 128B terminate at, and are operationally coupled to, central spray post 124 and side bowl spray post 132, respectively, such that the etching composition 18 is dispensed into chamber 118 through one or both of these spray posts. Either, both or neither of side bowl fluid supply line 128B and center bowl fluid supply line 128A may comprise optional valve 134 to control the flow of etching composition 18.

Generally, central spray post 124 and side bowl spray post 132 include at least one complementary set, and preferably a plurality of complementary sets, of passages through which streams of etching composition supplied to central spray post 124 and side bowl spray post 132 can be ejected in such a manner that at least one ejected stream of etching composition impacts another ejected fluid stream which may be a gas (such as nitrogen) or a liquid such as a complementary ejected stream of etching composition. The etching composition is atomized into a mist of droplets 18 as a result.

Rotatable support 12 includes a top surface 14, a bottom surface 18, and a sidewall 110. The surface 14 of rotatable support 12 supports one or more substrate cassettes 116 that hold a plurality of semiconductor wafer substrates 16 above rotatable support 12. Rotatable support 12 is itself supported on motor-driven shaft 120, which is capable of causing rotatable support 12 to rotate about an axis 122 central to motor-driven shaft 120.

During substrate stripping, a desired flow rate of etching composition is dispensed from central spray post 124 and/or side bowl spray post 132) in the form of atomized droplets of etching composition 18. Although the particular overall flow rate achievable from each spray post will depend on the viscosity of the etching composition utilized in the system of the present invention, the flow rate of etching composition delivered from each spray post will preferably be from about 2 liters per minute to about 16 liters per minute.

During the delivery of the etching composition, rotatable support 12 can be caused to rotate to more evenly deposit the etching composition on the substrates 16. If rotatable support 12 is desirably rotated, it is preferred that the rate of rotation be from about 20 rpm to about 500 rpm, more preferably from about 20 rpm to about 300 rpm, most preferably from about 60 rpm to about 200 rpm.

Although the etching composition in accordance with the present invention exhibits the aforementioned desirable strip selectivity and strip rate at substantially ambient temperature, it may be desirable to heat the etching composition in some applications. Thus, etching composition supply 136 may further optionally include heating coil 142 operationally located so as to be capable of heating the etching composition, and temperature probe 144 so that such heating is capable of being monitored. Such heating may also be achieved, e.g., via the inclusion of an on line heater (not shown) operationally located in relation to fluid supply line 128 so as to be capable of heating the etching composition.

Exhaust and drain lines 112 are provided so that etching composition (and/or a purging gas, if employed) may be vented from chamber 118. Additionally, fluid supply line 128 and/or exhaust and drain lines 112 may optionally comprise a flow regulating device (not shown) to regulate the flow of etching composition and exhaust, respectively. Recycling line 146 is provided so that any unused etching composition that may remain after an etch sequence can be returned to etching composition supply 136.

In operation, system 10 could be used to reclaim a semiconductor wafer bearing a film stack comprising a polysilicon-containing film overlying an oxide film as follows. One or more semiconductor wafer substrates 16 bearing such a film stack would be supportably placed in substrate cassette(s) 116. Rotatable support 12 would be caused to rotate at 60 rpm, while the etching composition in accordance with the present invention is caused to spray out of central spray post 124 and side bowl spray post 132 at a flow rate at the substrate surface of about 10 liters per minute. During this dispensation, rotatable support 12 is accelerated to a rotation rate of 200 rpm. Dispensation of etching composition is ceased once the polysilicon film has been removed, at which time a standard rinse sequence is initiated. The dispense time is dependent upon the thickness of the film to be removed, and is typically from about 3 to about 5 minutes.

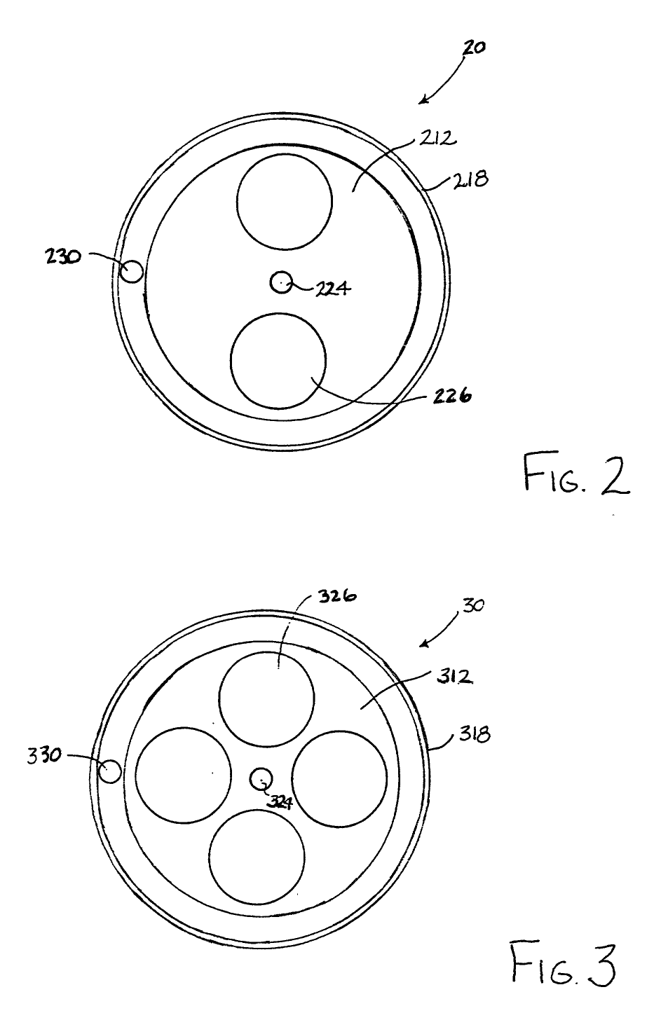

A preferred embodiment of system 10 is illustrated in FIG. 2. The embodiment of system 20 shown in FIG. 2 is generally identical to system 10 illustrated in FIG. 1, with the exception that system 20 illustrates both central spray post 224 and peripheral spray post 230. Etching composition may be delivered from either one or both of central spray post 224 and/or peripheral spray post 230. If etching composition is to be delivered from both central spray post 224 and peripheral spray post 230, it is preferred that the volume ratio of etching composition delivered from central spray post 224 to etching composition delivered from peripheral spray post 230 be from about 7:3 to about 5:5.

An additional preferred embodiment of system 10 is illustrate in FIG. 3 to further illustrate the manner in which the number and placement of substrate cassettes may be varied in the practice of the method of the present invention. In particular, the embodiment of system 30 shown in FIG. 3 is generally identical to system illustrate in FIG. 1, with the exception that four substrate cassettes are arranged at substantially regular intervals around the periphery of rotating support 312.

The present invention will be described below with reference to the following representative examples.

### EXAMPLE 1

The following experiment was conducted to demonstrate the polysilicon/oxide stripping selectivity of an etching composition in accordance with the present invention. Specifically, 20 liters of an etching composition in accordance with the present invention was prepared by combining 19 liters of nitric acid (69.3-70 weight % solids) and 1 liter of hydrofluoric acid (48.5-49.2 weight % solids) to provide an etching composition with 95 volume percent of nitric acid and 5 volume percent hydrofluoric acid and 66.5 weight percent nitric acid, 2.5 weight percent hydrofluoric acid and 31 weight percent water. The resulting etching composition was added to the etching composition reservoir of a MERCURY® centrifugal spray processor. One silicon wafer have a polysilicon film overlying an oxide film was placed in one substrate cassette and one silicon wafer having only an oxide film was placed into a second substrate cassette in an opposing position on the rotatable support from the first substrate cassette. The film thickness on the wafers was measured both before and after etching at nine (9) different points.

The rotatable support was initially caused to rotate at 60 rpm prior to dispensing any etching composition. Once the rotatable support attained 60 rpm, etching composition was dispensed through the center and side bowl spray posts onto the surface of the wafers at approximately 10 liters per minute. During dispensation, the rotatable support was caused to accelerate to a speed of 200 rpm. Etching composition was dispensed for a total of 4 minutes, after which time, dispensation of the etching composition was ceased and a standard rinse sequence was initiated.

The wafer comprising the polysilicon film lost an average of 10 microns in film thickness, i.e., the etching composition of the present invention etched the polysilicon film at a rate of 2.5 microns per minute. On the other hand, the wafer comprising only the oxide film lost an average of only 0.2 microns in film thickness, i.e., the etching composition of the present invention etched the oxide film at a rage of 0.05 microns per minute. Thus, the polysilicon/oxide stripping selectivity exhibited by the etching composition was 2.5/0.05 or about 50:1.

### EXAMPLE 2

The following experiment was conducted to demonstrate that the polysilicon/oxide stripping selectivity of an etching composition in accordance with the present invention allows a polysilicon film to be effectively stripped from an underlying oxide film, while leaving the oxide film substantially unetched, i.e., the oxide film acts as a “stop layer”. Specifically, 20 liters of an etching composition in accordance with the present invention was prepared as in Example 1 and added to the etching composition reservoir of a MERCURY® centrifugal spray processor. Two groups of ten (10) silicon wafers bearing a film stack comprising a polysilicon film overlying an oxide film were placed into separate substrate cassettes placed in opposing positions on the rotatable support. The thickness of the polysilicon film on each wafer was about 10 microns, whereas the thickness of the oxide film was about 0.55 to 0.65 microns.

The rotatable support was initially caused to rotate at 60 rpm prior to dispensing any etching composition. Once the rotatable support attained 60 rpm, etching composition was dispensed through the center and side bowl spray posts onto the surface of the wafers at approximately 10 liters per minute. During dispensation, the rotatable support was caused to accelerate to a speed of 200 rpm. Etching composition was dispensed for a total of 5 minutes, after which time, dispensation of the etching composition was ceased and a standard rinse sequence was initiated.

It was found that the etching composition effectively removed the polysilicon layer from each of the wafers, and further that, on average, only 0.05 to 0.1 microns of the oxide layer was removed, i.e., about 70% to 90% of the oxide layer remained on the surface of the wafer. The remaining oxide film layer was subsequently effectively stripped off using conventional hydrofluoric acid chemistry to finish the wafer reclamation process.

Thus, this example shows that, when utilizing an etching composition according to the present invention, an oxide film underlying a polysilicon film can effectively act as a “stop layer”, thereby protecting the underlying wafer for damage during the wafer reclamation process.

### EXAMPLE 3

The following experiment was conducted to demonstrate the polysilicon/oxide stripping selectivity of another etching composition in accordance with the present invention. Specifically, 20 liters of an etching composition in accordance with the present invention was prepared by combining 19.5 liters of nitric acid (69.3-70 weight % solids) and 0.5 liters of hydrofluoric acid (48.5-49.2 weight % solids) to provide an etching composition with 97.5 volume percent of nitric acid and 2.5 volume percent hydrofluoric acid and 68.25 weight percent nitric acid, 1.25 weight percent hydrofluoric acid and 30.5 weight percent water. The resulting etching composition was added to the etching composition reservoir of a MERCURY® centrifugal spray processor. One silicon wafer have a polysilicon film overlying an oxide film was placed in one substrate cassette and one silicon wafer having only an oxide film was placed into a second substrate cassette in an opposing position on the rotatable support from the first substrate cassette. The film thickness on the wafers was measured both before and after etching at nine (9) different points.

The rotatable support was initially caused to rotate at 60 rpm prior to dispensing any etching composition. Once the rotatable support attained 60 rpm, etching composition was dispensed through the center and side bowl spray posts onto the surface of the wafers at approximately 10 liters per minute. During dispensation, the rotatable support was caused to accelerate to a speed of 200 rpm. Etching composition was dispensed for a total of 5 minutes, after which time, dispensation of the etching composition was ceased and a standard rinse sequence was initiated.

The wafer comprising the polysilicon film lost an average of 5 microns in film thickness, i.e., the etching composition of the present invention etched the polysilicon film at a rate of 1 microns per minute. On the other hand, the wafer comprising only the oxide film lost an average of only 0.1 microns in film thickness, i.e., the etching composition of the present invention etched the oxide film at a rage of 0.02 microns per minute. Thus, the polysilicon/oxide stripping selectivity exhibited by the etching composition was 1/0.02 or about 50:1.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

What is claimed is:

1. A method of reclaiming a semiconductor wafer substrate bearing a film stack comprising a polysilicon-containing film overlying an oxide film, said method comprising the steps of:
(a) causing an aqueous, acidic etching composition to contact the polysiliconcontaining film under conditions effective to remove at least a portion of the polysiliconcontaining film from the semiconductor wafer substrate thereby exposing the oxide film, wherein the etching composition comprises an oxidant and a fluoride ion source, and wherein the weight ratio of the oxidant to the fluoride ion source is sufficiently high such that the etching composition has a polysilicon/oxide stripping selectivity of at least about 2 or more; and
(b) removing the exposed oxide film from the semiconductor wafer substrate.

2. The method of claim 1, wherein the etching composition has a polysilicon/oxide stripping selectivity of from about 10:1 to about 100:1.

3. The method of claim 1, wherein the etching composition has a polysilicon/oxide stripping selectivity of from about 10:1 to about 50:1.

4. The method of claim 1, wherein the oxidant comprises nitric acid.

5. The method of claim 1, wherein the fluoride ion source comprises hydrofluoric acid.

6. The method of claim 1, wherein the oxidant comprises nitric acid and wherein the fluoride ion source is hydrofluoric acid.

7. The method of claim 1, wherein the etching composition comprises less than 5% of hydrofluoric acid and at least 35% nitric acid, with the remainder of the etching composition comprising water.

8. The method of claim 1, wherein the etching composition comprises from about 0.01% to about 5% hydrofluoric acid and from about 50% to about 97% nitric acid, with the remainder of the etching composition comprising water.

9. The method of claim 1, wherein the etching composition comprises from about 0.5% to about 3% hydrofluoric acid and from about 65% to about 70% nitric acid, with the remainder of the etching composition comprising water.

10. The method of claim 1, wherein the etching composition comprises from about 2% to about 5% hydrofluoric acid and from about 95% to about 97% nitric acid, with the remainder of the etching composition comprising water.

11. The method of claim 1, wherein the step of causing the etching composition to contact the polysilicon-containing film occurs at substantially ambient temperature.

12. The method of claim 1, wherein the step of removing the exposed oxide film from the semiconductor wafer substrate comprises causing a fluoride ion source to contact the exposed oxide film.

13. The method of claim 12, wherein the fluoride ion source comprises hydrofluoric acid.

14. The method of claim 1, wherein the step of causing the etching composition to contact the polysilicon-containing film comprises contacting the polysilicon-containing film with the etching composition while the semiconductor wafer substrate is supported on a rotating support.

15. The method of claim 14, wherein the step of contacting the polysilicon-containing film comprises causing at least one fluid stream comprising the etching composition to flowably contact the semiconductor wafer substrate.

16. The method of claim 15, wherein the step of contacting the polysilicon-containing film comprises spraying the etching composition onto the semiconductor wafer substrate.

17. The method of claim 16, wherein the step of contacting the polysilicon-containing film comprises positioning the semiconductor wafer substrate within a chamber comprising a central spray post and spraying the etching composition from the central spray post.

18. The method of claim 16, wherein the step of contacting the polysilicon-containing film comprises positioning the semiconductor wafer substrate within a chamber comprising a peripheral spray post and spraying the etching composition from the peripheral spray post.

19. The method of claim 16, wherein the step of contacting the polysilicon-containing film comprises positioning the semiconductor wafer substrate within a chamber comprising a central spray post and a peripheral spray post and spraying the etching composition from the central spray post and the peripheral spray post.

20. A method of reclaiming a semiconductor wafer substrate bearing a film stack comprising a polysilicon-containing film overlying an oxide film, said method comprising the steps of:
(a) causing an aqueous, acidic etching composition to contact the polysiliconcontaining film under conditions effective to remove at least a portion of the polysiliconcontaining film from the semiconductor wafer substrate thereby exposing the oxide film, wherein the etching composition comprises nitric acid and hydrofluoric acid, and wherein the weight ratio of the nitric acid to hydrofluoric acid is sufficiently high such that the etching composition has a polysilicon/oxide stripping selectivity of at least about 2 or more; and
(b) removing the exposed oxide film from the semiconductor wafer substrate.

21. The method of claim 20, wherein the etching composition has a polysilicon/oxide stripping selectivity of from about 10:1 to about 100:1.

22. The method of claim 20, wherein the etching composition has a polysilicon/oxide stripping selectivity of from about 10:1 to about 50:1.

23. The method of claim 20, wherein the etching composition comprises from about 0.01% to about 5% hydrofluoric acid and from about 50% to about 97% nitric acid, with the remainder of the etching composition comprising water.

24. The method of claim 20, wherein the etching composition comprises from about 0.5% to about 3% hydrofluoric acid and from about 65% to about 70% nitric acid, with the remainder of the etching composition comprising water.

25. An aqueous, acidic etching composition, comprising:
(a) an oxidant; and
(b) a fluoride ion source; and
wherein the weight ratio of the oxidant to the fluoride ion source is sufficiently high such that the etching composition has a polysilicon/oxide stripping selectivity of at least about 2 or more

26. The method of claim 25, wherein the etching composition has a polysilicon/oxide stripping selectivity of from about 10:1 to about 100:1.

27. The method of claim 25, wherein the etching composition has a polysilicon/oxide stripping selectivity of from about 10:1 to about 50:1.

28. The method of claim 25, wherein the oxidant comprises nitric acid.

29. The method of claim 25, wherein the fluoride ion source comprises hydrofluoric acid.

30. The method of claim 25, wherein the oxidant comprises nitric acid and wherein the fluoride ion source is hydrofluoric acid.

31. The method of claim 25, wherein the etching composition comprises less than 5% of hydrofluoric acid and at least 35% nitric acid, with the remainder of the etching composition comprising water.

32. The method of claim 25, wherein the etching composition comprises from about 0.01% to about 5% hydrofluoric acid and from about 50% to about 97% nitric acid, with the remainder of the etching composition comprising water.

33. The method of claim 25, wherein the etching composition comprises from about 0.5% to about 3% hydrofluoric acid and from about 65% to about 70% nitric acid, with the remainder of the etching composition comprising water.
